(19) United States
(12) Patent Application Publication
(10) Pub. No.: US 2017/0310280 A1
(43) Pub. Date: Oct. 26, 2017

(54) SINGLE SIGNAL-VARIANT POWER SUPPLY FOR A PLURALITY OF AMPLIFIERS

(71) Applicant: Cirrus Logic International Semiconductor Ltd., Edinburgh (GB)

(72) Inventors: Jeffrey LaBUNDY, Austin, TX (US); Anu CHAKRAVARTY, Austin, TX (US); Deepal SHRISHRIMAL, Austin, TX (US); Jeffrey Allen MAY, Dripping Springs, TX (US); Firas AZRAI, Austin, TX (US)

(73) Assignee: Cirrus Logic International Semiconductor Ltd., Edinburgh (GB)

(21) Appl. No.: 15/349,771

(22) Filed: Nov. 11, 2016

Related U.S. Application Data
(60) Provisional application No. 62/325,231, filed on Apr. 20, 2016.

(51) Int. Cl. H03F 1/02; H03F 3/217; H03F 3/21; H04R 3/12; H03F 3/187

(52) U.S. Cl. CPC H03F 1/0216; H04R 3/12; H03F 3/187; H03F 3/211; H03F 3/2175

(57) ABSTRACT

In accordance with embodiments of the present disclosure a control circuit may include at least one input for monitoring a respective signal for each of a plurality of amplifiers, an output for outputting at least one control signal for controlling a power supply level of the single signal-variant power supply configured to deliver electrical energy to the plurality of amplifiers, and decision and control logic. The decision and control logic may be configured to monitor the respective signals for each of the plurality of amplifiers and, based on the respective signals, and a respective requirement associated with each of the plurality of amplifiers, setting a power supply level of the single signal-variant power supply and outputting the at least one control signal to control the power supply level such that the respective requirements are satisfied.

### RELATED APPLICATIONS

The present disclosure claims priority to U.S. Provisional Patent Application Ser. No. 62/325,231, filed Apr. 20, 2016, which is incorporated by reference herein in its entirety.

### FIELD OF DISCLOSURE

The present disclosure relates in general to circuits for audio devices, including without limitation personal audio devices such as wireless telephones and media players, and more specifically, to a single signal-variant power supply for supplying a supply voltage to a plurality of amplifiers or other load.

### BACKGROUND

Personal audio devices, including wireless telephones, such as mobile/cellular telephones, cordless telephones, mp3 players, and other consumer audio devices, are in widespread use. Such personal audio devices may include circuitry for driving a pair of headphones or one or more speakers. Such circuitry often includes a power amplifier for driving an audio output signal to headphones or speakers. Generally speaking, a power amplifier amplifies an audio signal by taking energy from a power supply and controlling an audio output signal to match an input signal shape but with a larger amplitude. Although many amplifier architectures (e.g., Class A, Class B, and Class AB amplifiers) provide for only a single power supply for a power amplifier, some architectures provide for at least two supply voltages for powering a power amplifier, in order to achieve greater power efficiency over single or constant power supply voltage architectures.

One example of a multi-supply voltage amplifier is a Class H amplifier. A Class H amplifier may have an infinitely variable voltage supply rail that tracks an envelope of an output signal of the Class H amplifier. In order to provide such an infinitely variable voltage supply rail, the output supply rail may be modulated such that the rail is only slightly larger than a magnitude of the audio output signal at any given time. For example, switched-mode power supplies may be used to create the output signal-tracking voltage rails. Accordingly, a Class H amplifier may increase efficiency by reducing the wasted power at output driving transistors of the amplifier.

Many audio systems are configured to process and reproduce audio signals on a plurality of channels. For example, stereo audio systems may include a left audio channel and a right audio channel. As another example, some audio systems may include a low-frequency channel (e.g., for reproducing audio via a “woofer”) and a high-frequency channel (e.g., for reproducing audio via a “tweeter”). Accordingly, for cases in which two or more audio channels can be supplied from a single voltage supply, it may be advantageous to do so, in order to reduce size, cost, and complexity of an audio system. However, to supply power from a single voltage supply to a plurality of Class H amplifier channels may be challenging, as each of the plurality of channels may have varying supply requirements, a problem not adequately addressed using traditional approaches.

### SUMMARY

In accordance with the teachings of the present disclosure, one or more disadvantages and problems associated with existing approaches to supplying voltages to a plurality of amplifiers may be reduced or eliminated.

In accordance with embodiments of the present disclosure, a method may include monitoring a respective signal for each of a plurality of amplifiers and, based on the respective signals, and a respective requirement associated with each of the plurality of amplifiers, setting a power supply level of a single signal-variant power supply configured to deliver electrical energy to the plurality of amplifiers such that the respective requirements are satisfied.

In accordance with these and other embodiments of the present disclosure a control circuit may include at least one input for monitoring a respective signal for each of a plurality of amplifiers, an output for outputting at least one control signal for controlling a power supply level of the single signal-variant power supply configured to deliver electrical energy to the plurality of amplifiers, and decision and control logic. The decision and control logic may be configured to monitor the respective signals for each of the plurality of amplifiers and, based on the respective signals, and a respective requirement associated with each of the plurality of amplifiers, set a power supply level of the single signal-variant power supply and outputting the at least one control signal to control the power supply level such that the respective requirements are satisfied.

In accordance with these and other embodiments of the present disclosure, an apparatus may include a plurality of amplifiers, a single signal-variant power supply configured to deliver electrical energy to the plurality of amplifiers, and a control circuit. The control circuit may be configured to monitor a respective signal for each of the plurality of amplifiers and, based on the respective signals, and a respective requirement associated with each of the plurality of amplifiers, set a power supply level of the single signal-variant power supply such that the respective requirements are satisfied.

Technical advantages of the present disclosure may be readily apparent to one skilled in the art from the figures, description and claims included herein. The objects and advantages of the embodiments will be realized and achieved at least by the elements, features, and combinations particularly pointed out in the claims.

It is to be understood that both the foregoing general description and the following detailed description are examples and explanatory and are not restrictive of the claims set forth in this disclosure.

### BRIEF DESCRIPTION OF THE DRAWINGS

A more complete understanding of the present embodiments and advantages thereof may be acquired by referring to the following description taken in conjunction with the accompanying drawings, in which like reference numbers indicate like features, and wherein:

FIG. 1 is an illustration of an example personal audio device, in accordance with embodiments of the present disclosure;

FIG. 2 is a block diagram of selected components of an example audio integrated circuit of a personal audio device, in accordance with embodiments of the present disclosure;

FIG. 3 is a block diagram of selected components of another example audio integrated circuit of a personal audio device, in accordance with embodiments of the present disclosure; and

FIG. 4 is a block diagram of selected components of yet another example audio integrated circuit of a personal audio device, in accordance with embodiments of the present disclosure.

### DETAILED DESCRIPTION

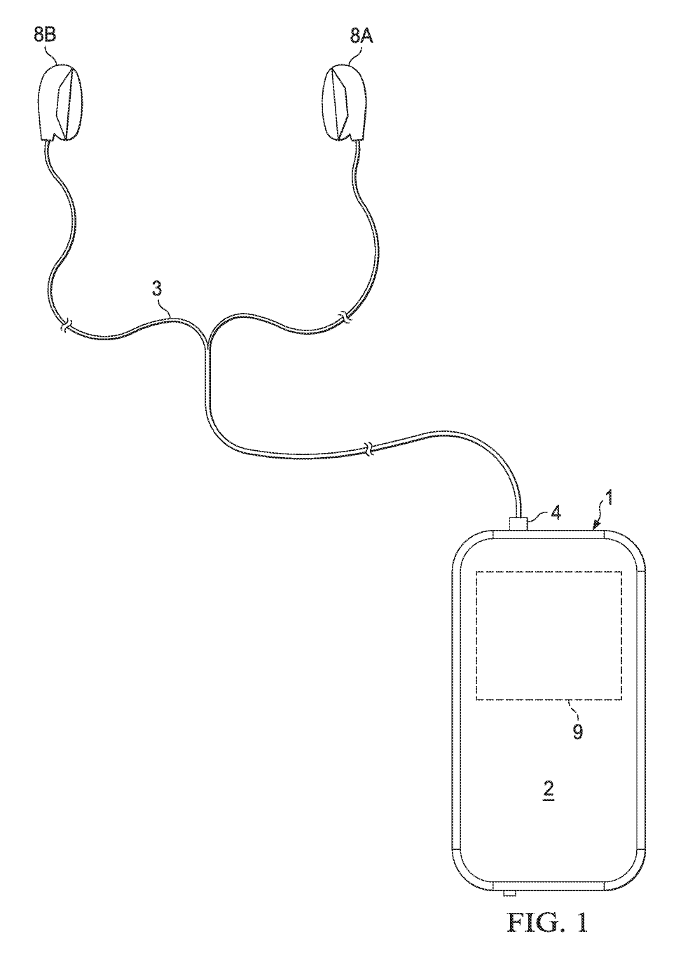

FIG. 1 is an illustration of an example personal audio device 1, in accordance with embodiments of the present disclosure. FIG. 1 depicts personal audio device 1 coupled to a headset 3 in the form of a pair of earbud speakers 8A and 8B. Headset 3 depicted in FIG. 1 is merely an example, and it is understood that personal audio device 1 may be used in connection with a variety of audio transducers, including without limitation, headphones, earbuds, in-ear earphones, and external speakers. A plug 4 may provide for connection of headset 3 to an electrical terminal of personal audio device 1. Personal audio device 1 may provide a display to a user and receive user input using a touch screen 2, or alternatively, a standard liquid crystal display (LCD) may be combined with various buttons, sliders, and/or dials disposed on the face and/or sides of personal audio device 1. As also shown in FIG. 1, personal audio device 1 may include an audio integrated circuit (IC) 9 for generating an analog audio signal for transmission to headset 3 and/or another audio transducer.

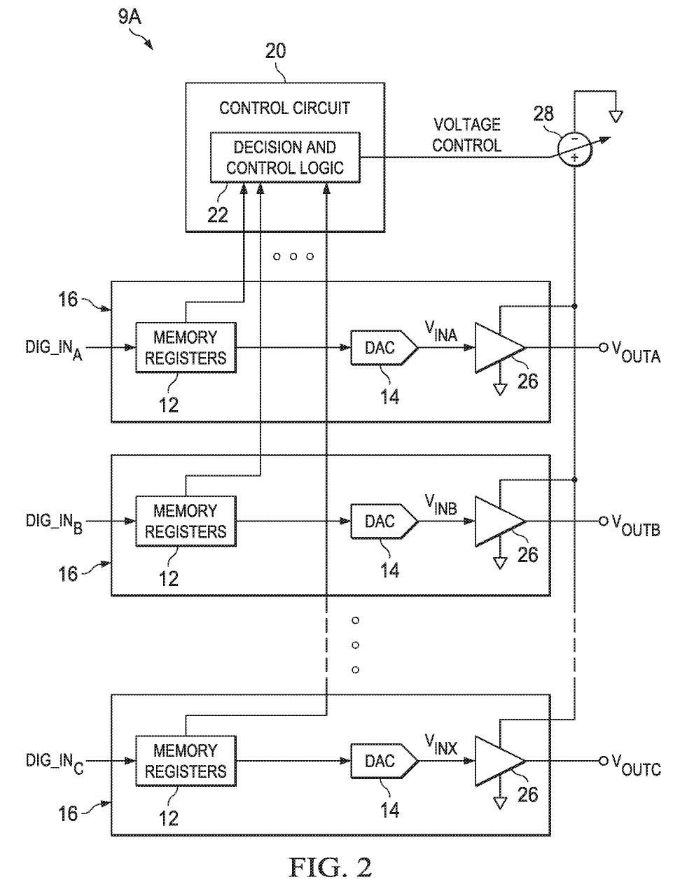

FIG. 2 is a block diagram of selected components of an example audio system 9A of a personal audio device, in accordance with embodiments of the present disclosure. In some embodiments, example audio system 9A may be used to implement audio system 9 of FIG. 1. As shown in FIG. 2, audio system 9A may include a plurality of amplifiers 16, a control circuit 20, and a signal-variant power supply 28. Each amplifier 16 may be configured to convert a respective digital audio input signal (e.g., DIG_IN_{A}, DIG_IN_{B}, . . . , DIG_IN_{X}, which may be referred to herein generically as “DIG_IN”) into a respective analog audio output signal (e.g., V_{OUTA}, V_{OUTB}, . . . , V_{OUTX}, which may be referred to herein generically as “V_{OUT}”) to be driven to a respective audio transducer (e.g., earbud speakers 8A and 8B) for reproduction of the audio signal. For example, in some embodiments, each amplifier 16 may process and amplify a particular channel of audio for playback (e.g., left channel or right channel, low-frequency channel or high-frequency channel).

As shown in FIG. 2, each amplifier 16 may include memory registers 12 configured to buffer such amplifier's respective digital audio input signal DIG_IN. Such buffering may impose a delay in the audio processing path for a particular channel, which may allow time for control (e.g., control of a supply voltage of an amplifier 16) of amplifier 16 prior to the audio signal propagating to the output of amplifier 16 of the channel. Each amplifier 16 may include a digital-to-analog converter (DAC) 14, which may receive the buffered digital audio input signal DIG_IN for the respective channel and convert such buffered digital audio input signal to a respective analog signal V_{IN} (e.g., V_{INA}, V_{INB}, . . . , V_{INX}, which may be referred to herein generically as “V_{IN}”). DAC 14 may supply analog signal V_{IN} to an output stage amplifier 26 which may amplify or attenuate audio input signal V_{IN} to provide a respective audio output signal V_{OUT}, which may operate a speaker, headphone transducer, a line level signal output, and/or other suitable output. An output stage amplifier 26 may comprise any suitable output stage for driving an analog signal to a transducer, including without limitation a Class D amplifier, a Class AB amplifier, a Class G amplifier, and a Class H amplifier. In addition, although the foregoing contemplates driving the respective output signals V_{OUT} to audio transducers, transducers driven by the various amplifiers 16 may include any suitable transducer, including without limitation an acoustic loudspeaker, a headphone earpiece, a haptic transducer, and an ultrasonic emitter.

As depicted in FIG. 2, output stage amplifier 26 of each amplifier 16 may be supplied electrical energy from signal-variant power supply 28. Signal-variant power supply 28 may output a variable supply voltage V_{SUPPLY} based on one or more control signals VOLTAGE CONTROL communicated from control circuit 20, as described in greater detail below. Supply voltage V_{SUPPLY} output by signal-variant power supply 28 may be selected from a plurality of discrete voltages, or may include an infinite number of voltages between a minimum and maximum voltage. Signal-variant power supply 28 may comprise any suitable power supply for supplying electrical energy to a load, including without limitation, a boost converter power supply, a buck converter power supply, a buck-boost converter power supply, and a linear power supply.

Control circuit 20 may include at least one input for receiving a respective signal for each of the plurality of amplifiers 16, an output for outputting at least one control signal (e.g., VOLTAGE CONTROL) for controlling the power supply level of single signal-variant power supply 26, and decision and control logic 22. Decision and control logic 22 may be configured to monitor the respective signals received from each of the plurality of amplifiers 16 and, based on the respective signals, and a respective requirement associated with each of the plurality of amplifiers 16, set a power supply level of single signal-variant power supply 26 and output the at least one control signal (e.g., VOLTAGE CONTROL) to control the power supply level such that the respective requirements are satisfied.

For example, monitoring the respective signals may comprise monitoring respective signal content of the respective signals, the signal content comprising one or more of a voltage level (e.g., a voltage level of an audio output voltage V_{OUT} to be generated from a digital audio input signal DIG_IN), a current level (e.g., a target current driven into a load based on a digital audio input signal DIG_IN), a mathematical derivative or mathematical integral of the voltage level, a mathematical derivative or mathematical integral of the current level, and in-band spectral content of an audio output voltage V_{OUT} or digital audio input signal DIG_IN. Decision and control logic 22 may receive such information from the respective memory registers 12 of the various amplifiers 16 or may determine such information from data received from the respective memory registers 12 of the various amplifiers 16. Communication from memory registers 12 of the various amplifiers 16 to decision and control logic 22 may be via any suitable digital communication protocol or analog communication protocol. In addition to signal content communicated from memory registers 12 of the various amplifiers 16 to decision and control logic 22, memory registers 12 or other components of amplifiers 16 may also communicate requirements for the amplifiers. Such requirements may include any suitable requirements for an amplifier 16 or an audio output signal generated by such amplifier, including without limitation an acceptable distortion level, an acceptable noise level, a required voltage supply headroom, a frequency range, and/or any other suitable requirement. Thus, in some embodiments, the requirements may be communicated via the communication protocol using variables representing advisory controls of the plurality of amplifiers 16.

As a specific example, in some embodiments, decision and control logic 22 may receive from each amplifier 16 a respective signal (e.g., the buffered digital audio input signal DIG_IN or a signal derived therefrom) and a voltage headroom requirement for such amplifier 16. Then, based on the respective signals and the respective requirements, decision and control logic 22 may determine for each amplifier 16 a respective minimum-required power supply level sufficient to satisfy the respective requirement (e.g., the headroom requirement) of such amplifier 16. Such that the headroom requirement is satisfied for each amplifier 16, decision and control logic 22 may set the power supply level of signal-variant power supply 28 to a maximum of the respective minimum-required power supply levels.

In these and other embodiments, decision and control logic 22 may set the power supply level of signal-variant power supply 28 based on any suitable analysis of the respective signals received from the various amplifiers 16, including one or more of a frequency analysis of the respective signals, a time domain analysis of the respective signals, a power consumption optimization setting for the plurality of amplifiers, and a target distortion for at least one of the plurality of amplifiers.

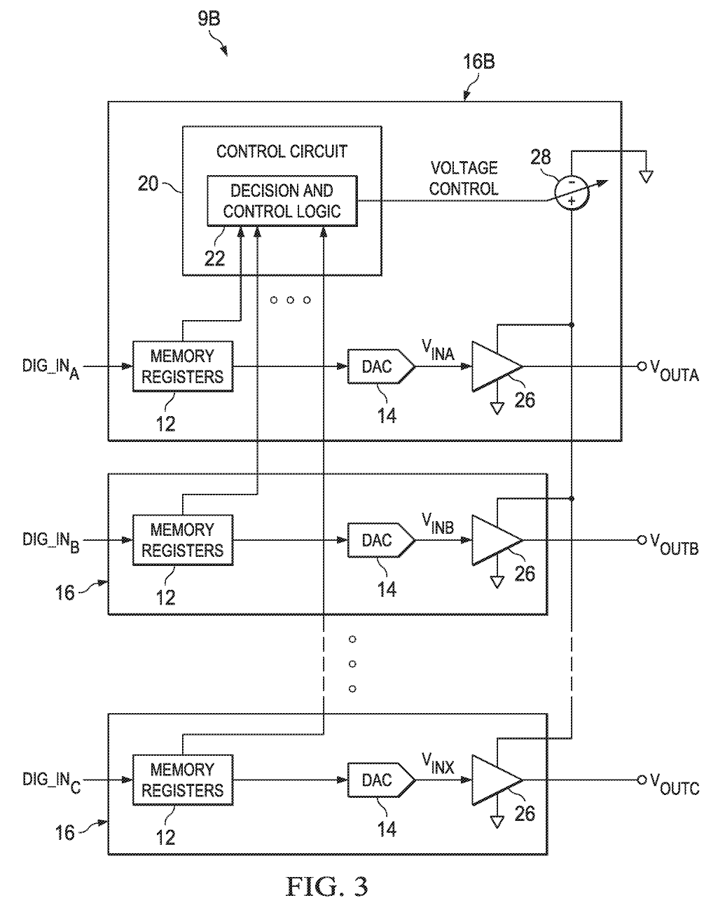

FIG. 3 is a block diagram of selected components of an example audio system 9B of a personal audio device, in accordance with embodiments of the present disclosure. In some embodiments, example audio system 9B may be used to implement audio system 9 of FIG. 1. The structure and function of example audio system 9B is in many respects identical to that of example audio system 9A, except that in example audio system 9B, control circuit 20 and signal-variant power supply 28 are internal to an amplifier 16B of the plurality of amplifiers 16.

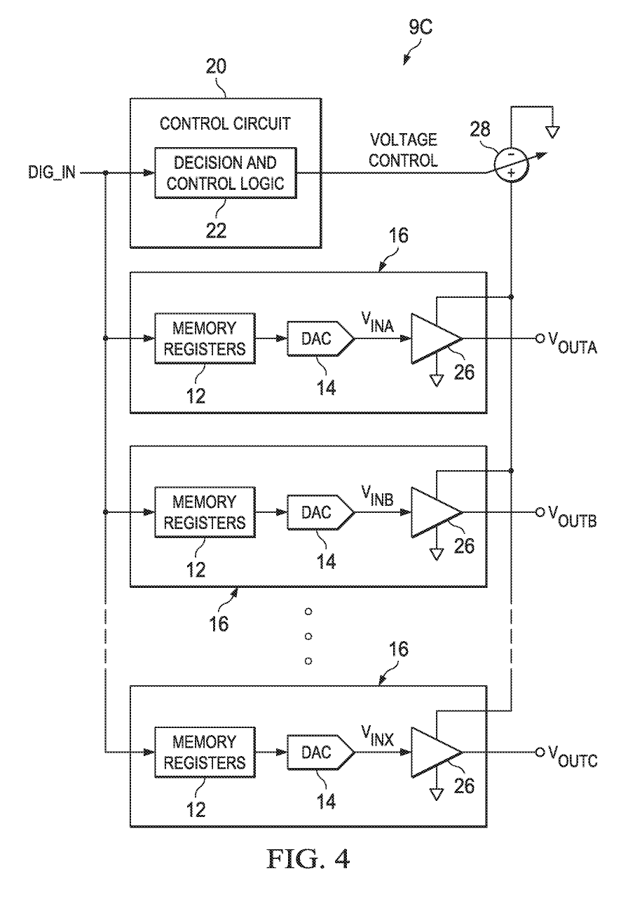

FIG. 4 is a block diagram of selected components of an example audio system 9C of a personal audio device, in accordance with embodiments of the present disclosure. In some embodiments, example audio system 9C may be used to implement audio system 9 of FIG. 1. The structure and function of example audio system 9C is in many respects identical to that of example audio system 9A, except that in example audio system 9C, each amplifier 16 may be responsible for reproducing the output content of only a single channel of a digital audio input signal DIG_IN delivered over a common digital interface, and decision and control logic 22 may receive and process all channels of digital audio input signal DIG_IN and requirements of the various amplifiers 16 in order to set the supply voltage of signal-variant power supply 28. Although control circuit 20 and signal-variant power supply 28 are depicted in FIG. 4 as external to each amplifier 16, in some embodiments, one or more of control circuit 20 and signal-variant power supply 28 may be internal to an amplifier 16.

In the various examples above, the various components of audio systems 9A, 9B, and 9C may be implemented on a single integrated circuit or on a plurality of coupled integrated circuits.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding the invention and the concepts contributed by the inventor to furthering the art, and are construed as being without limitation to such specifically recited examples and conditions. Although embodiments of the present inventions have been described in detail, it should be understood that various changes, substitutions, and alterations could be made hereto without departing from the spirit and scope of the disclosure.

What is claimed is:

1. A method comprising:
monitoring a respective signal for each of a plurality of amplifiers; and
based on the respective signals, and a respective requirement associated with each of the plurality of amplifiers, setting a power supply level of a single signal-variant power supply configured to deliver electrical energy to the plurality of amplifiers such that the respective requirements are satisfied.

2. The method of claim 1, further comprising:
based on the respective signals and the respective requirements, determining for each amplifier a respective minimum-required power supply level sufficient to satisfy the respective requirement of such amplifier; and
setting the power supply level to a maximum of the respective minimum-required power supply levels.

3. The method of claim 1, wherein the signal-variant power supply comprises one of a boost converter power supply, a buck converter power supply, a buck-boost converter power supply, and a linear power supply.

4. The method of claim 1, wherein the signal-variant power supply is internal to one of the plurality of amplifiers.

5. The method of claim 1, wherein the signal-variant power supply is external to the plurality of amplifiers.

6. The method of claim 1, wherein each of the plurality of amplifiers comprises one of a Class D amplifier, a Class AB amplifier, a Class G amplifier, and a Class H amplifier.

7. The method of claim 1, wherein each amplifier drives a respective output signal to a respective load, wherein each of the respective loads comprises one of an acoustic loudspeaker, a headphone earpiece, a haptic transducer, and an ultrasonic emitter.

8. The method of claim 1, wherein monitoring comprises monitoring respective signal content of the respective signals, the signal content comprising one or more of a voltage level, a current level, a mathematical derivative or mathematical integral of the voltage level, a mathematical derivative or mathematical integral of the current level, and in-band spectral content.

9. The method of claim 1, wherein setting the power supply level is based on one or more of frequency analysis of the respective signals, a time domain analysis of the respective signals, a power consumption optimization setting for the plurality of amplifiers, and a target distortion for at least one of the plurality of amplifiers.

10. The method of claim 1, comprising communicating at least one of the respective characteristics of the respective signals and respective requirements from at least one of the plurality of amplifiers using a communication protocol.

11. The method of claim 10, wherein the communication protocol comprises one of an analog communication protocol and a digital communication protocol.

12. The method of claim 10, wherein the communication protocol uses variables representing advisory controls of the plurality of amplifiers.

13. The method of claim 12, wherein the variables are shared within register spaces of the plurality of amplifiers.

14. A control circuit comprising:
at least one input for receiving a respective signal for each of a plurality of amplifiers;
an output for outputting at least one control signal for controlling a power supply level of the single signal-variant power supply configured to deliver electrical energy to the plurality of amplifiers; and
decision and control logic configured to:
monitor the respective signals for each of the plurality of amplifiers; and
based on the respective signals, and a respective requirement associated with each of the plurality of amplifiers, set a power supply level of the single signal-variant power supply and output the at least one control signal to control the power supply level such that the respective requirements are satisfied.

15. The control circuit of claim 14, wherein the decision and control logic is further configured to:
based on the respective signals and the respective requirements, determine for each amplifier a respective minimum-required power supply level sufficient to satisfy the respective requirement of such amplifier; and
set the power supply level to a maximum of the respective minimum-required power supply levels.

16. The control circuit of claim 14, wherein the signal-variant power supply comprises one of a boost converter power supply, a buck converter power supply, a buck-boost converter power supply, and a linear power supply.

17. The control circuit of claim 14, wherein the signal-variant power supply is internal to one of the plurality of amplifiers.

18. The control circuit of claim 14, wherein the signal-variant power supply is external to the plurality of amplifiers.

19. The control circuit of claim 14, wherein each of the plurality of amplifiers comprises one of a Class D amplifier, a Class AB amplifier, a Class G amplifier, and a Class H amplifier.

20. The control circuit of claim 14, wherein each amplifier drives a respective output signal to a respective load, wherein each of the respective loads comprises one of an acoustic loudspeaker, a headphone earpiece, a haptic transducer, and an ultrasonic emitter.

21. The control circuit of claim 14, wherein the decision and control logic is configured to monitor the respective signals by monitoring respective signal content of the respective signals, the signal content comprising one or more of a voltage level, a current level, a mathematical derivative or mathematical integral of the voltage level, a mathematical derivative or mathematical integral of the current level, and in-band spectral content.

22. The control circuit of claim 14, wherein the decision and control logic is configured to set the power supply level based on one or more of frequency analysis of the respective signals, a time domain analysis of the respective signals, a power consumption optimization setting for the plurality of amplifiers, and a target distortion for at least one of the plurality of amplifiers.

23. The control circuit of claim 14, wherein the control circuit is configured to receive via the at least one input at least one of the respective requirements of the respective signals and respective requirements from at least one of the plurality of amplifiers using a communication protocol.

24. The control circuit of claim 23, wherein the communication protocol comprises one of an analog communication protocol and a digital communication protocol.

25. The method of claim 23, wherein the communication protocol uses variables representing advisory controls of the plurality of amplifiers.

26. The method of claim 25, wherein the variables are shared within register spaces of the plurality of amplifiers.

27. An apparatus comprising:
a plurality of amplifiers;
a single signal-variant power supply configured to deliver electrical energy to the plurality of amplifiers; and
a control circuit configured to:
monitor a respective signal for each of the plurality of amplifiers; and
based on the respective signals, and a respective requirement associated with each of the plurality of amplifiers, set a power supply level of the single signal-variant power supply such that the respective requirements are satisfied.
